(19) United States
(12) Patent Application Publication
(10) Pub. No.: US 2026/0143994 A1
(43) Pub. Date: May 21, 2026

(54) PLASMA PROCESSING APPARATUS AND PLASMA PROCESSING METHOD

(71) Applicant: PANASONIC INTELLECTUAL PROPERTY MANAGEMENT CO., LTD., Osaka (JP)

(72) Inventors: Shotaro OGAWA, Osaka (JP); Ryota FURUKAWA, Osaka (JP)

(21) Appl. No.: 19/382,554

(22) Filed: Nov. 7, 2025

(30) Foreign Application Priority Data
Nov. 20, 2024 (JP) 2024-202766

(51) Int. Cl. H01L 21/67; H01J 37/32

(52) U.S. Cl. CPC H10P 72/0421; H01J 37/32568; H01J 37/32743; H01J 2237/3341

(57) ABSTRACT

A plasma processing apparatus performs plasma processing on a first surface of a substrate including the first surface and a second surface. The plasma processing apparatus includes a base, a lower electrode, a lid including an upper electrode and ascending and descending between a raised position and a lowered position, and a guide unit. The guide unit is configured to guide the substrate conveyed with the first surface facing downward to a space between the lower electrode and the upper electrode when the lid is at the raised position, and to support the substrate with the first surface facing downward at a first position in the space when the lid is at the lowered position. The first position is set to be a position where a first vertical distance is greater than a second vertical distance when the lid is at the lowered position.

### BACKGROUND

### 1. Technical Field

The present disclosure relates to a plasma processing apparatus and a plasma processing method.

### 2. Description of the Related Art

[Conventionally, a plasma processing apparatus for performing plasma processing on a substrate is known (for example, PTL 1). The plasma processing apparatus of PTL 1 includes a base, a lower electrode attached to the base via an insulator and to which high-frequency power is applied, and a lid including an upper electrode provided above the lower electrode and capable of being raised and lowered between a raised position and a lowered position, and is configured to perform plasma processing on the substrate in a sealed space formed between the lid at the lowered position and the base.

### Citation List

### Patent Literature

PTL 1: Japanese Patent No. 4281692

### SUMMARY

In the plasma processing apparatus of PTL 1, plasma processing of a reactive ion etching method (hereinafter, RIE method) is performed by applying high-frequency power to the lower electrode on which the substrate is placed. On the other hand, as plasma processing other than the RIE method, there is plasma processing of a plasma etching method (hereinafter, PE method) in which plasma processing is performed by applying high-frequency power to the upper electrode facing the lower electrode on which the substrate is placed. Since the PE method can reduce the energy of ions incident on the substrate as compared with the RIE method, plasma processing with suppressed damage to the substrate can be performed. If the plasma processing apparatus to which the high-frequency power is applied to the lower electrode can perform the low-damage plasma processing equivalent to the PE method, it is possible to expand the range of applicable substrate and process conditions corresponding to the plasma processing apparatus, but such a technique has not been sufficiently considered so far. In such a situation, an object of the present disclosure is to perform plasma processing of a PE method in a plasma processing apparatus with a lower electrode that is supplied with high-frequency power.

One aspect according to the present disclosure relates to a plasma processing apparatus. The plasma processing apparatus is a plasma processing apparatus for plasma-processing a first surface of a substrate including the first surface and a second surface opposite to the first surface, the plasma processing apparatus comprising: a base to be grounded; a lower electrode that is attached to the base via an insulator and receives high-frequency power; and a lid that includes an upper electrode arranged above the lower electrode and grounded, and ascends and descends between a raised position where the lid is separated above the base and a lowered position where the lid abuts on the base to form a sealed space; and a guide unit attached to the base, wherein the guide unit is configured to: guide the substrate conveyed with the first surface facing downward to a space between the lower electrode and the upper electrode in a case where the lid is at the raised position, and support the substrate with the first surface facing downward at a first position in the space in a case where the lid is at the lowered position, and the first position is set to a position where a first vertical distance between the first surface and the lower electrode is greater than a second vertical distance between the second surface and the upper electrode in a case where the lid is at the lowered position.

Another aspect according to the present disclosure relates to a plasma processing method. The plasma processing method is a plasma processing method executed by a plasma processing apparatus for plasma-processing a first surface of a substrate including the first surface and a second surface opposite to the first surface, the plasma processing apparatus including: a base to be grounded; a lower electrode attached to the base via an insulator; and a lid that includes an upper electrode arranged above the lower electrode and grounded, and ascends and descends between a raised position where the lid is separated above the base and a lowered position where the lid abuts on the base to form a sealed space, the plasma processing method comprising: guiding the substrate conveyed with the first surface facing downward to a space between the lower electrode and the upper electrode in a case where the lid is at the raised position; supporting the substrate with the first surface facing downward at a first position in the space in a case where the lid is at the lowered position; and applying high-frequency power to the lower electrode to perform plasma processing on the first surface in a state where the lid is at the lowered position, wherein the first position is set to a position where a first vertical distance between the first surface and the lower electrode is greater than a second vertical distance between the second surface and the upper electrode in a case where the lid is at the lowered position.

According to the present disclosure, plasma processing of a PE method can be performed by a plasma processing apparatus with a lower electrode that is supplied with high-frequency power.

### BRIEF DESCRIPTION OF THE DRAWINGS

FIG. 1 is a cross-sectional view schematically illustrating an example of a plasma processing apparatus according to the present disclosure in a state where a lid is at a raised position;

FIG. 2 is a cross-sectional view schematically illustrating the plasma processing apparatus of FIG. 1, in a state where the lid is at a lowered position;

FIG. 3 is a cross-sectional view illustrating a state where a different type of guide unit is applied to the plasma processing apparatus of FIG. 1, in a state where the lid is at the raised position;

FIG. 4 is a cross-sectional view illustrating a state where a different type of guide unit is applied to the plasma processing apparatus of FIG. 1, in a state where the lid is at the lowered position; and

FIG. 5 is a graph showing experimental data on an amount of metal fine particles deposited on a first surface of a substrate by plasma processing where a vertical axis represents a deposition amount of metal fine particles and a horizontal axis represents a first vertical distance.

### DETAILED DESCRIPTIONS

Exemplary embodiments of a plasma processing apparatus and a plasma processing method according to the present disclosure will be described below with reference to examples. However, the present disclosure is not limited to the examples described below. Although specific numerical values and materials may be provided as examples in the description below, other numerical values and materials may be used as long as an effect of the present disclosure can be obtained.

### Plasma processing apparatus

A plasma processing apparatus according to the present disclosure is an apparatus for performing plasma processing on a first surface of a substrate (for example, a semiconductor substrate) including the first surface and a second surface. The plasma processing apparatus may be, for example, a plasma cleaner, a plasma etching apparatus, a plasma dicer, a plasma ashing apparatus, or a plasma CVD apparatus. The plasma processing apparatus includes a base, a lower electrode, a lid, and a guide unit.

The base is grounded. The base may be formed of a metal (for example, aluminum or an aluminum alloy). The base may have an opening opened upward.

The lower electrode is attached to the base via an insulator, and high-frequency power is applied to the lower electrode. The lower electrode may be connected to a power supply including a high-frequency power supply and an automatic matching device. The lower electrode may be formed of metal (for example, aluminum or an aluminum alloy). The lower electrode may be formed in a plate shape.

The lid includes an upper electrode arranged above the lower electrode and grounded. In other words, the upper electrode of the lid is disposed to face the lower electrode in the vertical direction. The lid can ascend and descend between a raised position which is a position where the lid separates from the base and a lowered position which is a position where the lid abuts on the base to form a sealed space (that is, a processing space for performing the plasma processing on the substrate). In a case where the lid is at the raised position, the substrate can be carried in and out of the space between the lower electrode and the upper electrode. In a case where the lid is at the lowered position, the substrate can be subjected to plasma processing by applying high-frequency power to the lower electrode while introducing a raw material gas (for example, a gas containing oxygen) into the sealed space in the decompressed state. The lid may be formed of metal (for example, aluminum or an aluminum alloy).

The guide unit is attached to the base. The guide unit is configured to guide the substrate conveyed (or carried) with the first surface (or a surface to be treated) facing downward to a space (or an inter-electrode space) between the lower electrode and the upper electrode in a case where the lid is at the raised position, and to support the substrate with the first surface facing downward at a first position (or a predetermined position) in the space in a case where the lid is at the lowered position. The first position is set to be a position where a first vertical distance between the first surface of the substrate and the lower electrode is greater than a second vertical distance between the second surface of the substrate and the upper electrode in a case where the lid is at the lowered position. In other words, in a case where the lid is at the lowered position, the substrate at the first position is positioned closer to the upper electrode than the lower electrode in the vertical direction.

In the plasma processing apparatus including the above-described configuration, in a case where the lid is at the lowered position (or in a case where a sealed space is formed between the base and the lid), the plasma processing of the PE method is performed on the first surface of the substrate at the first position. At this time, since the substrate at the first position is relatively distant from the lower electrode, even if the lower electrode is sputtered during the plasma processing, metal fine particles generated by the sputtering are less likely to adhere to the first surface of the substrate. In addition, since the guide unit is attached to the base instead of the lower electrode, abnormal discharge is less likely to occur in plasma processing.

The guide unit may include a first support portion (or a substrate support portion) that supports an edge of the substrate with the first surface facing downward, and a second support portion (or a unit leg) that includes a lower end fixed to the base and supports the first support portion. The first support portion may have at least a pair of guide members extending along the conveyance direction of the substrate and including a groove. At least one pair of guide members may support the edge of the substrate by the edge of the substrate entering the groove included in each of the guide members. An example of the material forming the guide members includes metal oxide such as alumina and silica, metal nitride such as silicon nitride and aluminum nitride, and other insulating ceramic materials. The second support portion may have a spring that can expand and contract in the vertical direction, or may be formed of a columnar member not including such a spring.

The first vertical distance in a case where the substrate is at the first position may be equal to or greater than 40 mm. In this case, even when the lower electrode is sputtered at the time of performing the plasma processing, it is possible to further suppress the metal fine particles generated by the sputtering from adhering to the first surface of the substrate. The first vertical distance in a case where the substrate is at the first position may be equal to or greater than 50 mm or equal to or greater than 60 mm.

The first vertical distance in a case where the substrate is at the first position may be equal to or less than 110 mm. In this case, by avoiding the sealed space formed between the base and the lid from becoming excessively large (or by reducing the volume of the sealed space), the efficiency of the plasma processing can be maintained high. The first vertical distance in a case where the substrate is at the first position may be equal to or less than 100 mm or equal to or less than 90 mm.

The second vertical distance in a case where the substrate is at the first position may be less than 110 mm, and is preferably less than 40 mm. The ratio of the second vertical distance to the first vertical distance (second vertical distance/first vertical distance) in a case where the substrate is at the first position may be less than 1. In these cases, the efficiency of the plasma processing can be further enhanced.

### Plasma processing method

The plasma processing method according to the present disclosure may be executed in the above-described plasma processing apparatus, or may be executed in another plasma processing apparatus or plasma processing system. Specifically, a plasma processing apparatus applying the plasma processing method according to the present disclosure is a plasma processing apparatus for performing plasma processing on a first surface of a substrate including the first surface and a second surface on an opposite side of the first surface, the plasma processing apparatus including: a base to be grounded; a lower electrode attached to the base via an insulator; and a lid including an upper electrode arranged above the lower electrode and grounded, the lid being capable of ascending and descending between a raised position where the lid is separated above the base and a lowered position where the lid abuts on the base to form a sealed space. Each of these components may be similar to each component included in the plasma processing apparatus described above. The plasma processing method according to the present disclosure includes guiding, supporting, and applying.

In the guiding, in a case where the lid is at the raised position, the substrate conveyed with the first surface facing downward is guided to the space between the lower electrode and the upper electrode. The guiding may be referred to as carrying the substrate into the space.

In the supporting, in a case where the lid is at the lowered position, the substrate with the first surface facing downward is supported at the first position in the space. That is, in the supporting, the substrate is supported at the first position in the sealed space formed between the base and the lid. For this support, any element can be used as long as the element can support the substrate at the first position.

In the applying, the first surface is subjected to plasma processing by applying high-frequency power to the lower electrode in a state where the lid is at the lowered position. That is, in the applying, the first surface of the substrate at the first position is subjected to plasma processing. Here, the first position is set to be a position where a first vertical distance between the first surface and the lower electrode is greater than a second vertical distance between the second surface and the upper electrode in a case where the lid is at the lowered position. Therefore, in the applying, the plasma processing of the PE method is executed on the substrate.

As described above, according to the present disclosure, the plasma processing apparatus with the lower electrode receiving the high-frequency power can perform the plasma processing of the PE method by the guide unit that supports the substrate at the predetermined first position. Further, according to the present disclosure, by setting the first vertical distance greater than the second vertical distance, it is possible to prevent metal fine particles generated by sputtering of the lower electrode during plasma processing from adhering to the first surface of the substrate.

Hereinafter, an example of a plasma processing apparatus and a plasma processing method according to the present disclosure will be specifically described with reference to the drawings. The above-described components and processes can be applied to the components and processes of the plasma processing apparatus and the plasma processing method as an example described below. Components and processes of the plasma processing apparatus and the plasma processing method as an example described below can be changed based on the above description. In addition, matters to be described below may be applied to the exemplary embodiment described above. Among the components and processes of the plasma processing apparatus and the plasma processing method as an example described below, components and processes that are not essential to the plasma processing apparatus and the plasma processing method according to the present disclosure may be omitted. The drawings illustrated below are schematic, and thus do not accurately reflect the shape and number of actual members.

Hereinafter, first, the configuration of plasma processing apparatus 10 of the present exemplary embodiment will be described, and then, the plasma processing method of the present exemplary embodiment will be described.

### Plasma processing apparatus

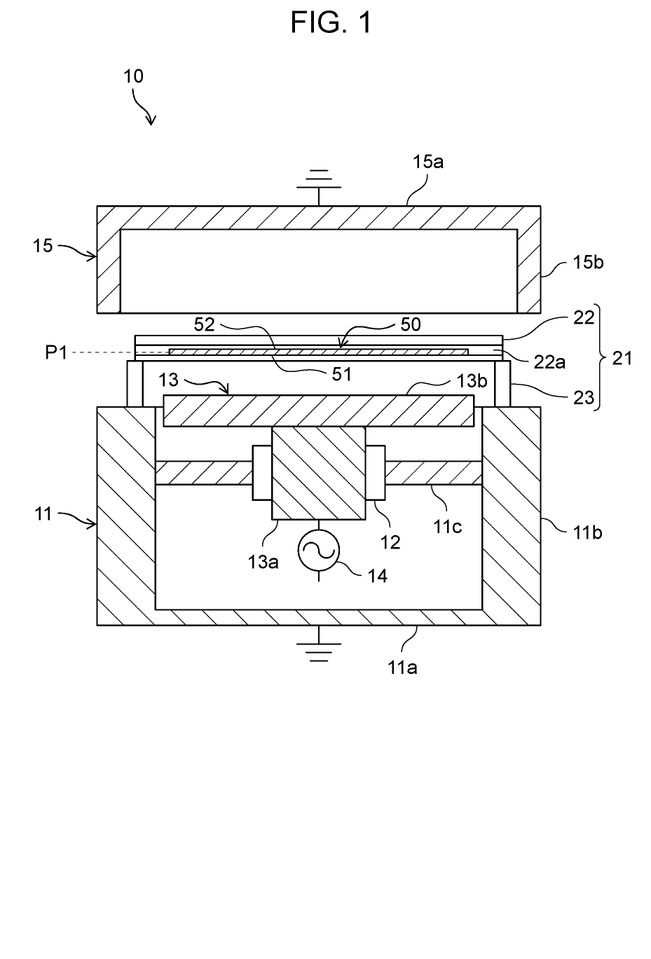

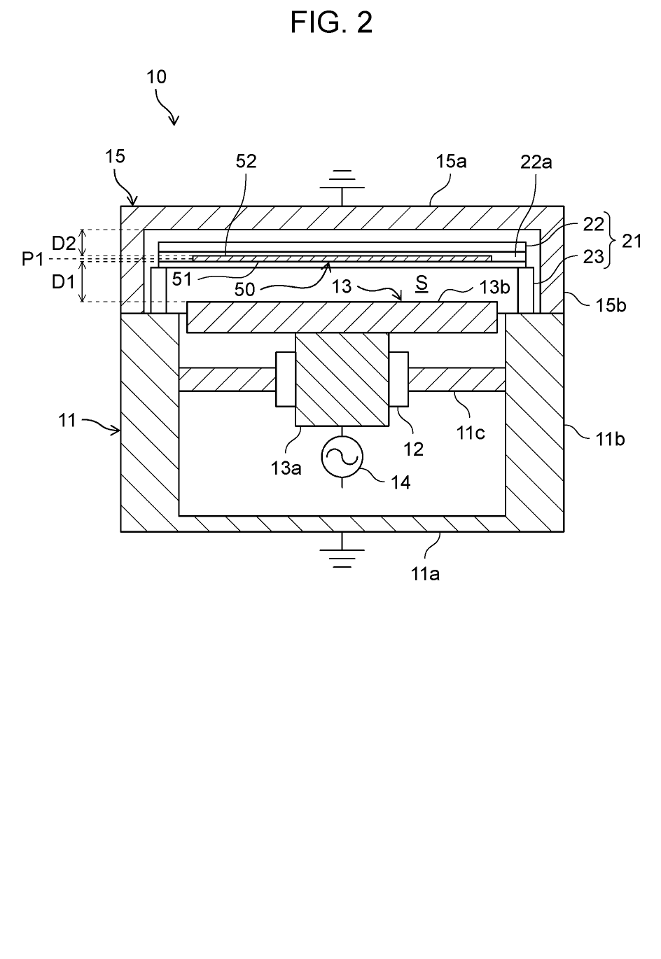

Plasma processing apparatus 10 of the present exemplary embodiment is a plasma cleaner for plasma-cleaning first surface 51 of substrate 50 including first surface 51 and second surface 52, but is not limited thereto. As illustrated in FIGS. 1 and 2, plasma processing apparatus 10 includes base 11, lower electrode 13, lid 15, and first guide unit 21.

Base 11 is formed in a substantially rectangular cylindrical shape as a whole. Base 11 is formed of metal (in this example, an aluminum alloy) and grounded. Base 11 includes bottom plate 11a including a substantially rectangular shape, side wall portion 11b including a substantially rectangular cylindrical shape rising from a peripheral edge of bottom plate 11a, and extending portion 11c extending radially inward from an inner wall of side wall portion 11b. Extending portion 11c includes insulator 12 including a wide ring shape at a distal end. Base 11 includes an opening opened upward.

Lower electrode 13 is attached to base 11 via insulator 12. Lower electrode 13 is formed of metal (in this example, an aluminum alloy). Lower electrode 13 includes block portion 13a including a substantially prismatic shape attached to insulator 12 and plate portion 13b including a substantially rectangular shape fixed to an upper end of block portion 13a. Block portion 13a is connected to high-frequency power supply 14 via a matching device (not illustrated), and high-frequency power is applied to lower electrode 13 by high-frequency power supply 14. Plate portion 13b is disposed in the opening of base 11.

Lid 15 includes upper electrode 15a arranged above lower electrode 13 and grounded. Lid 15 is formed of metal (in this example, an aluminum alloy). Upper electrode 15a of lid 15 is formed in a rectangular shape extending substantially in the horizontal direction, and peripheral wall portion 15b including a substantially rectangular cylindrical shape extends downward from a peripheral edge of upper electrode 15a. Upper electrode 15a and peripheral wall portion 15b are integrally formed. Lid 15 can ascend and descend between a raised position (FIG. 1) which is a position where lid 15 is separated above base 11 and a lowered position (FIG. 2) which is a position where lid 15 abuts on base 11 to form sealed space S. In a case where lid 15 is at the raised position, substrate 50 can be carried in and out of plasma processing apparatus 10. In a case where lid 15 is at the lowered position, plasma processing (in this example, plasma cleaning processing) can be performed on substrate 50.

] First guide unit 21 is attached to base 11. First guide unit 21 includes first support portion 22 that supports an edge of substrate 50 with first surface 51 facing downward, and a plurality of (in this example, four) second support portions 23 that includes a lower end fixed to base 11 and supports first support portion 22. First support portion 22 of the present exemplary embodiment includes groove 22a extending in the conveyance direction (the left-right direction in FIGS. 1 and 2) of substrate 50, and the edge of substrate 50 enters groove 22a. Second support portion 23 of the present exemplary embodiment is formed in a columnar shape extending vertically, and includes a constant vertical length. First guide unit 21 is an example of a guide unit.

First guide unit 21 is configured to guide substrate 50 conveyed with first surface 51 facing downward to a space between lower electrode 13 and upper electrode 15a in a case where lid 15 is at the raised position. In this example, substrate 50 is guided to first position P1 in the space, but the present disclosure is not limited thereto. In addition, first guide unit 21 is configured to support substrate 50 with first surface 51 facing downward at first position P1 in the space in a case where lid 15 is at the lowered position. As illustrated in FIG. 2, first position P1 is set to be a position where first vertical distance D1 between first surface 51 of substrate 50 and lower electrode 13 is greater than second vertical distance D2 between second surface 52 of substrate 50 and upper electrode 15a in a case where lid 15 is at the lowered position.

First vertical distance D1 in a case where substrate 50 is at first position P1 is preferably equal to or greater than 40 mm. Furthermore, first vertical distance D1 in a case where substrate 50 is at first position P1 is preferably equal to or less than 110 mm.

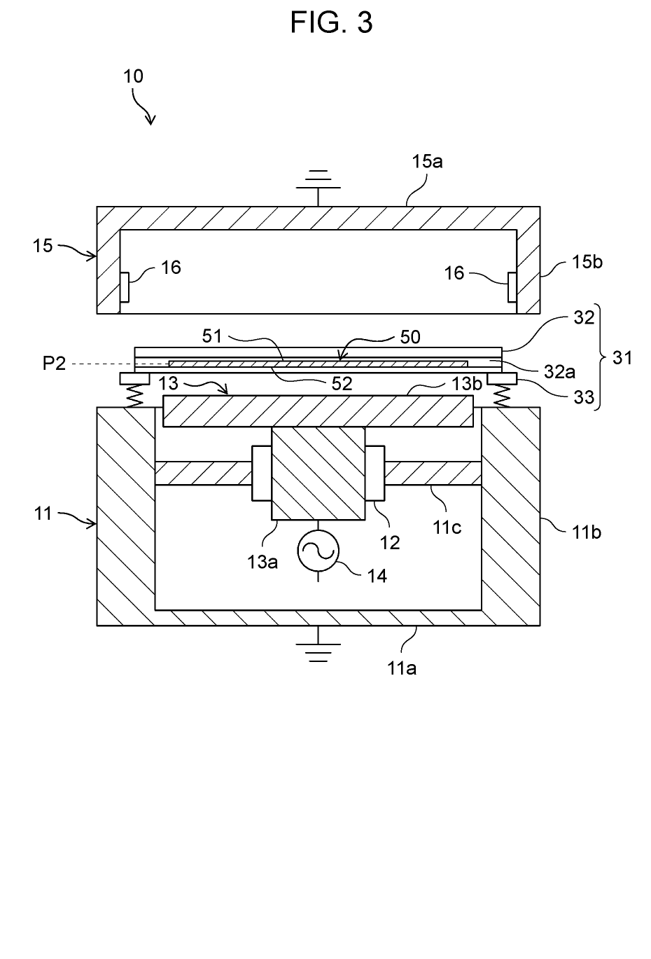

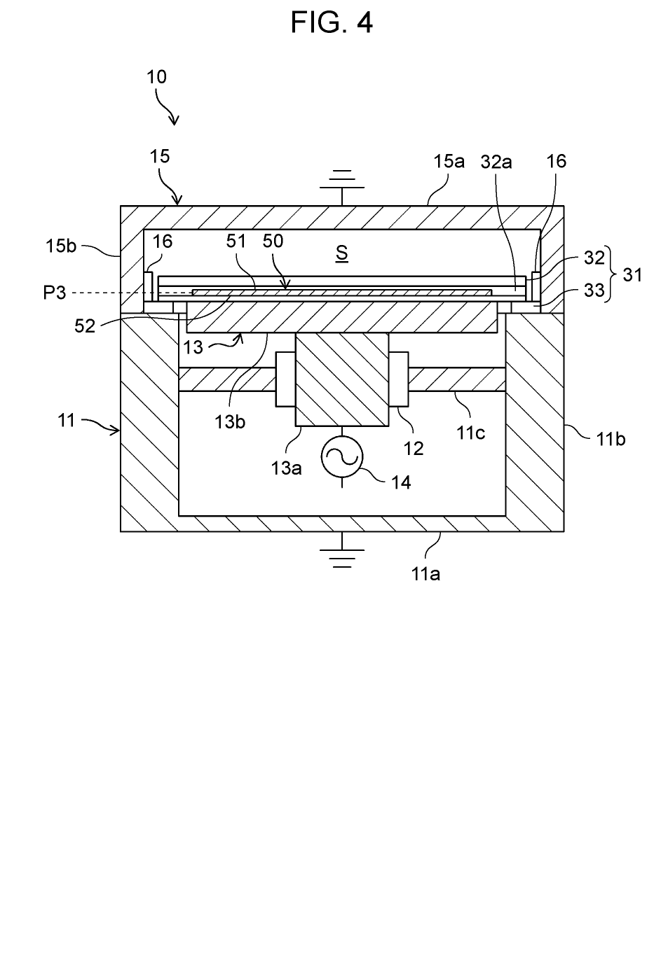

In plasma processing apparatus 10 including the configuration described above, the plasma processing of the PE method can be executed on substrate 50. On the other hand, it is also possible to perform the plasma processing of the RIE method in plasma processing apparatus 10 by replacing a part of the components. Next, switching of such a plasma processing method will be described with reference to FIGS. 3 and 4.

As illustrated in FIGS. 3 and 4, in a case where plasma processing apparatus 10 of the present exemplary embodiment performs plasma processing of the RIE method, first guide unit 21 is replaced with second guide unit 31, and pressing block 16 is attached to lid 15. Pressing block 16 includes a function of pushing down second guide unit 31 when lid 15 moves from the raised position (FIG. 3) to the lowered position (FIG. 4). Note that it is possible to perform the plasma processing of the PE method by switching to the configuration illustrated in FIGS. 1 and 2 by performing the reverse component replacement or the like, and it is also possible to perform the plasma processing of the PE method only by removing pressing block 16, that is, using second guide unit 31 although illustration is omitted.

Second guide unit 31 includes third support portion 32 that supports an edge of substrate 50 with first surface 51 facing upward, and a plurality of (in this example, four) fourth support portions 33 that have lower ends fixed to base 11 and support third support portion 32. The structure of third support portion 32 may be the same as the structure of first support portion 22. For example, third support portion 32 may have groove 32a extending in the conveyance direction (the left-right direction in FIGS. 3 and 4) of substrate 50, and the edge of substrate 50 may enter groove 32a. Fourth support portion 33 includes a vertically extendable spring, and its vertical length is variable.

Second guide unit 31 is configured to guide substrate 50 conveyed with first surface 51 facing upward to second position P2 between lower electrode 13 and upper electrode 15a in a case where lid 15 is at the raised position (FIG. 3). Second position P2 may be the same as or different from first position P1. In addition, second guide unit 31 is configured to support substrate 50, which is pressed down by pressing block 16 attached to lid 15 and includes first surface 51 facing upward, at third position P3 lower than second position P2 in a case where lid 15 is at the lowered position (FIG. 4). Second surface 52 of substrate 50 at third position P3 may be in contact with lower electrode 13 or may be slightly separated from lower electrode 13.

### Plasma processing method

The plasma processing method of the present exemplary embodiment can be executed in plasma processing apparatus 10 of the present exemplary embodiment as shown in FIGS. 1 and 2, but is not limited thereto. A plasma processing method includes guiding, supporting, and applying.

In the guiding, in a case where lid 15 is at the raised position (FIG. 1), substrate 50 conveyed with first surface 51 facing downward is guided to the space between lower electrode 13 and upper electrode 15a using first guide unit 21.

In the supporting, in a case where lid 15 is at the lowered position (FIG. 2), substrate 50 with first surface 51 facing downward is supported at first position P1 in the space by using first guide unit 21. First position P1 is the same as first position P1 described above.

In the applying, plasma is generated in sealed space S in the decompressed state by applying high-frequency power to lower electrode 13 in a state where lid 15 is at the lowered position, and first surface 51 of substrate 50 is subjected to plasma processing (in this example, a plasma cleaning processing of the PE method is performed).

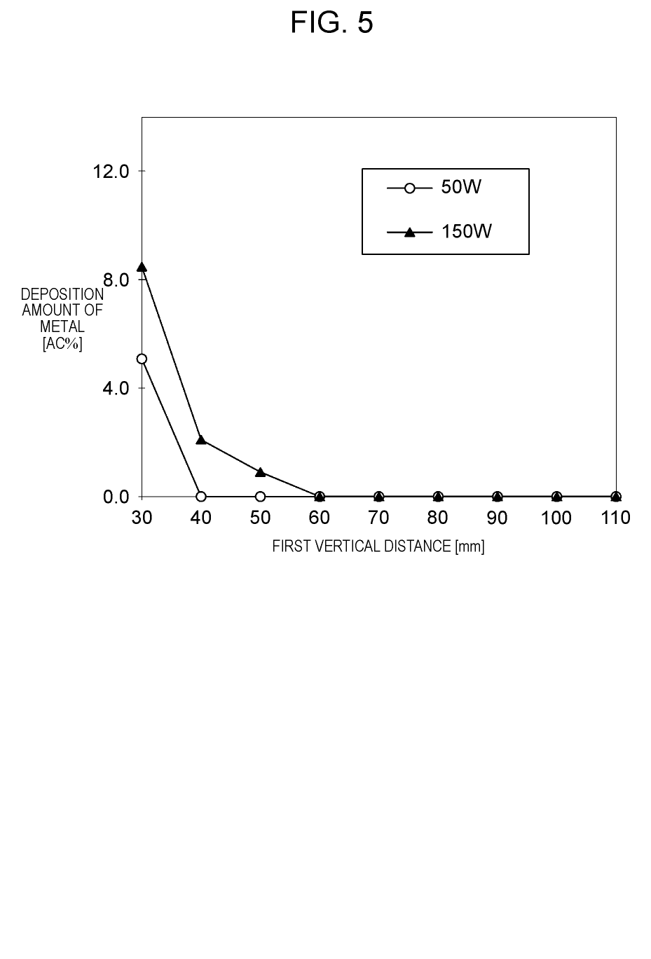

Here, in the applying, there is a risk that lower electrode 13 is sputtered during the plasma processing, and metal fine particles (in this example, aluminum fine particles) may be deposited on first surface 51 of substrate 50. On the other hand, by setting first vertical distance D1 in a case where substrate 50 is at first position P1 to equal to or greater than 40 mm, such deposition of metal fine particles can be suppressed. FIG. 5 is a graph showing the suppression effect. In the graph of FIG. 5, the vertical axis represents the amount (unit: AC %) of metal fine particles deposited on first surface 51 of substrate 50 by plasma processing, and the horizontal axis represents first vertical distance D1. A white circle indicates data when the plasma processing is performed by applying the high-frequency power of 50 W to lower electrode 13 for 1440 seconds, and a black triangle indicates data when the plasma processing is performed by applying the high-frequency power of 150 W to lower electrode 13 for 480 seconds. As can be seen from this graph, in a case where first vertical distance D1 is equal to or greater than 40 mm, the deposition amount of metal fine particles can be significantly reduced.

### Supplemental note

The above description of the exemplary embodiment discloses techniques below.

### Technique 1

A plasma processing apparatus for plasma-processing a first surface of a substrate

including the first surface and a second surface opposite to the first surface, the plasma

processing apparatus comprising:

a base to be grounded;

a lower electrode that is attached to the base via an insulator and receives high-

frequency power; and

a lid that includes an upper electrode arranged above the lower electrode and

grounded, and ascends and descends between a raised position where the lid is separated

above the base and a lowered position where the lid abuts on the base to form a sealed

space; and

a guide unit attached to the base,

wherein

the guide unit is configured to:

guide the substrate conveyed with the first surface facing downward to a space

between the lower electrode and the upper electrode in a case where the lid is at the raised position, and

support the substrate with the first surface facing downward at a first position in

the space in a case where the lid is at the lowered position, and

the first position is set to a position where a first vertical distance between the first

surface and the lower electrode is greater than a second vertical distance between the

second surface and the upper electrode in a case where the lid is at the lowered position.

### Technique 2

The plasma processing apparatus according to Technique 1, wherein

the guide unit includes:

a first support portion that supports an edge of the substrate with the first surface

facing downward; and

a second support portion that includes a lower end fixed to the base and supports

the first support portion.

### Technique 3

The plasma processing apparatus according to Technique 1 or 2, wherein the first

vertical distance in a case where the substrate is at the first position is equal to or greater

than 40 mm.

### Technique 4

The plasma processing apparatus according to Technique 3, wherein the first

vertical distance in a case where the substrate is at the first position is equal to or less than

110 mm.

### Technique 5

A plasma processing method executed by a plasma processing apparatus for

plasma-processing a first surface of a substrate including the first surface and a second

surface opposite to the first surface, the plasma processing apparatus including:

a base to be grounded;

a lower electrode attached to the base via an insulator; and

a lid that includes an upper electrode arranged above the lower electrode and

grounded, and ascends and descends between a raised position where the lid is separated

above the base and a lowered position where the lid abuts on the base to form a sealed

space,

the plasma processing method comprising:

guiding the substrate conveyed with the first surface facing downward to a space

between the lower electrode and the upper electrode in a case where the lid is at the raised

position;

of supporting the substrate with the first surface facing downward at a first

position in the space in a case where the lid is at the lowered position; and

applying high-frequency power to the lower electrode to perform plasma

processing on the first surface in a state where the lid is at the lowered position,

wherein

the first position is set to a position where a first vertical distance between the first

surface and the lower electrode is greater than a second vertical distance between the

second surface and the upper electrode in a case where the lid is at the lowered position.

### Technique 6

The plasma processing method according to Technique 5, wherein the first

vertical distance in a case where the substrate is at the first position is equal to or greater

than 40 mm.

### Technique 7

The plasma processing method according to Technique 6, wherein the first

vertical distance in a case where the substrate is at the first position is equal to or less

than 110 mm.

The present disclosure can be used for a plasma processing apparatus and a plasma processing method.

What is claimed is:

1. A plasma processing apparatus for plasma-processing a first surface of a substrate including the first surface and a second surface opposite to the first surface, the plasma processing apparatus comprising:
a base to be grounded;
a lower electrode that is attached to the base via an insulator and receives high-frequency power; and
a lid that includes an upper electrode arranged above the lower electrode and grounded, and ascends and descends between a raised position where the lid is separated above the base and a lowered position where the lid abuts on the base to form a sealed space; and
a guide unit attached to the base,
wherein
the guide unit is configured to:
guide the substrate conveyed with the first surface facing downward to a space between the lower electrode and the upper electrode in a case where the lid is at the raised position, and
support the substrate with the first surface facing downward at a first position in the space in a case where the lid is at the lowered position, and
the first position is set to a position where a first vertical distance between the first surface and the lower electrode is greater than a second vertical distance between the second surface and the upper electrode in a case where the lid is at the lowered position.

2. The plasma processing apparatus according to claim 1, wherein
the guide unit includes:
a first support portion that supports an edge of the substrate with the first surface facing downward; and
a second support portion that includes a lower end fixed to the base and supports the first support portion.

3. The plasma processing apparatus according to claim 1, wherein the first vertical distance in a case where the substrate is at the first position is equal to or greater than 40 mm.

4. The plasma processing apparatus according to claim 3, wherein the first vertical distance in a case where the substrate is at the first position is equal to or less than 110 mm.

5. A plasma processing method executed by a plasma processing apparatus for plasma-processing a first surface of a substrate including the first surface and a second surface opposite to the first surface, the plasma processing apparatus including:
a base to be grounded;
a lower electrode attached to the base via an insulator; and
a lid that includes an upper electrode arranged above the lower electrode and grounded, and ascends and descends between a raised position where the lid is separated above the base and a lowered position where the lid abuts on the base to form a sealed space,
the plasma processing method comprising:
guiding the substrate conveyed with the first surface facing downward to a space between the lower electrode and the upper electrode in a case where the lid is at the raised position;
supporting the substrate with the first surface facing downward at a first position in the space in a case where the lid is at the lowered position; and
applying high-frequency power to the lower electrode to perform plasma processing on the first surface in a state where the lid is at the lowered position,
wherein
the first position is set to a position where a first vertical distance between the first surface and the lower electrode is greater than a second vertical distance between the second surface and the upper electrode in a case where the lid is at the lowered position.

6. The plasma processing method according to claim 5, wherein the first vertical distance in a case where the substrate is at the first position is equal to or greater than 40 mm.

7. The plasma processing method according to claim 6, wherein the first vertical distance in a case where the substrate is at the first position is equal to or less than 110 mm.
